(19) United States
(12) Patent Application Publication
(10) Pub. No.: US 2024/0356307 A1
(43) Pub. Date: Oct. 24, 2024

(54) LASER MODULE

(71) Applicant: HAMAMATSU PHOTONICS K.K., Hamamatsu-shi (JP)

(72) Inventors: Takahide Ochiai, Hamamatsu-shi (JP); Atsushi Sugiyama, Hamamatsu-shi (JP); Tadataka Edamura, Hamamatsu-shi (JP)

(73) Assignee: HAMAMATSU PHOTONICS K.K., Hamamatsu-shi (JP)

(21) Appl. No.: 18/630,207

(22) Filed: Apr. 9, 2024

(30) Foreign Application Priority Data
Apr. 24, 2023 (JP) 2023-070940

(51) Int. Cl. H01S 5/34; H01S 5/00; H01S 5/02216; H01S 5/02253; H01S 5/14

(52) U.S. Cl. CPC H01S 5/3402; H01S 5/0064; H01S 5/02216; H01S 5/02253; H01S 5/141

(57) ABSTRACT

A laser module according to an embodiment includes a QCL element, a diffraction grating portion configured to diffract and reflect first light emitted from a first end face of the QCL element and return second light as a part of the first light to the first end face, a lens member configured to be disposed between the first end face and the diffraction grating portion and allow the first light and the second light to pass therethrough, and a lens holder configured to support the lens member. The lens member includes a first portion configured to constitute a collimator lens collimating the first light, and a second portion configured to be connected to an outer edge portion of the first portion and not to constitute the collimator lens when viewed from an X-axis direction.

### TECHNICAL FIELD

The present disclosure relates to a laser module.

### REFERENCE TO RELATED APPLICATIONS

This application claims the benefit of priority from Japanese Patent Application No. 2023-070940 filed on Apr. 24, 2023, the entire contents of which are incorporated herein by reference.

### BACKGROUND

As an external resonant laser module (hereinafter, simply referred to as “laser module”), a laser module including a quantum cascade laser element (hereinafter, referred to as “QCL element”), a diffraction grating portion, and a lens disposed between the QCL element and the diffraction grating portion is known (see, for example, Patent Literature 1 (US Patent Application Publication No. 2008/0298406)). In the laser module, light from the QCL element is diffracted and reflected by the diffraction grating portion, and light with a specific wavelength is returned to the QCL element. As a result, the light with a specific wavelength is amplified between the QCL element and the diffraction grating portion, and is output to the outside from an end face of the QCL element (an end face on the opposite side to the side of the diffraction grating portion).

### SUMMARY

In the laser module as described above, there is a high need for downsizing. For this reason, it is conceivable to use a lens with a smaller lens diameter than that of a conventional lens. However, if the lens diameter of the lens is reduced, it is difficult to support (hold or fix) the lens.

Therefore, an object of one aspect of the present disclosure is to provide a laser module capable of facilitating the support of a lens disposed between a QCL element and a diffraction grating portion while downsizing the laser module.

The present disclosure includes a laser module of [1] to [12] to be below.

[1] A laser module including:
a quantum cascade laser element having a stacked structure including an active layer and paired cladding layers arranged on both sides of the active layer, and a first end face and a second end face facing each other in a second direction orthogonal to a first direction as a stacking direction of the stacked structure, the quantum cascade laser element being configured to emit light from each of the first end face and the second end face;
a diffraction grating portion configured to diffract and reflect first light emitted from the first end face and return second light as a part of the first light to the first end face;
an optical member configured to be disposed between the first end face and the diffraction grating portion and allow the first light and the second light to pass therethrough; and
a support member configured to support the optical member, wherein
the optical member includes
a first portion configured to constitute a collimator lens collimating the first light, and
a second portion configured to be connected to an outer edge portion of the first portion when viewed from the second direction and not to constitute the collimator lens.

In the laser module of [1], the optical member disposed between the quantum cascade laser element (QCL element) and the diffraction grating portion includes the first portion constituting a collimator lens and the second portion that is connected to the outer edge portion of the first portion and does not constitute the collimator lens. According to the above configuration, the lens with a smaller lens diameter than that of a conventional lens can be easily implemented by the first portion. Here, the diffraction grating portion is preferably disposed at a position as close as possible to the beam waist position of the lens. That is, the diffraction grating portion is preferably irradiated with a beam close to parallel light. Therefore, by forming the lens (first portion) with a lens diameter smaller than that of a conventional lens as described above, the beam waist position can be brought close to the lens, and the diffraction grating portion can be disposed close to the optical member. As a result, the laser module can be downsized (can be made compact). In addition, in the second portion, the optical member can be supported (held) without hindering the lens function of the first portion. This makes it possible to achieve both downsizing of the first portion functioning as a collimator lens and ease of supporting the optical member. As described above, according to the laser module of [1], it is possible to facilitate the support of the lens (that is, the first portion included in the optical member) disposed between the QCL element and the diffraction grating portion while downsizing the laser module.

[2] A laser module including:
a quantum cascade laser element having a stacked structure including an active layer and paired cladding layers arranged on both sides of the active layer, and a first end face and a second end face facing each other in a second direction orthogonal to a first direction as a stacking direction of the stacked structure, the quantum cascade laser element being configured to emit light from each of the first end face and the second end face;
a diffraction grating portion configured to diffract and reflect first light emitted from the first end face and return second light as a part of the first light to the first end face;
an optical member configured to be disposed between the first end face and the diffraction grating portion and allow the first light and the second light to pass therethrough; and
a support member configured to support the optical member, wherein
the optical member includes
a first portion configured to include a first surface facing the diffraction grating portion and a second surface facing the quantum cascade laser element, and to cause at least the first surface to be formed in a curved surface shape convex toward the diffraction grating portion, and
a second portion configured to include a third surface connected to an outer edge portion of the first portion and having a planar portion when viewed from the second direction, and a fourth surface connected to an outer edge portion of the second surface and having a planar portion when viewed from the second direction.

In the laser module of [2], the optical member disposed between the quantum cascade laser element (QCL element) and the diffraction grating portion includes the first portion (that is, a portion functioning as a lens that suppresses the beam spread of light from the QCL element toward the diffraction grating portion) having the first surface formed in a curved surface shape convex toward the diffraction grating portion, and the second portion connected to the outer edge portion of the first portion.

According to the above configuration, the lens with a smaller lens diameter than that of a conventional lens can be easily implemented by the first portion. Here, the diffraction grating portion is preferably disposed at a position as close as possible to the beam waist position of the lens. That is, the diffraction grating portion is preferably irradiated with a beam close to parallel light. Therefore, by forming the lens (first portion) with a lens diameter smaller than that of a conventional lens as described above, the beam waist position can be brought close to the lens, and the diffraction grating portion can be disposed close to the optical member. As a result, the laser module can be downsized (can be made compact). In addition, in the second portion, the optical member can be supported (held) without hindering the lens function of the first portion. This makes it possible to achieve both downsizing of the first portion functioning as a lens and ease of supporting the optical member. As described above, according to the laser module, it is possible to facilitate the support of the lens (that is, the first portion included in the optical member) disposed between the QCL element and the diffraction grating portion while downsizing the laser module.

[3] The laser module according to [1], wherein at a boundary portion between the first portion and the second portion on a side of the optical member on which the diffraction grating portion is located, a curved surface portion included in the first portion and a planar portion included in the second portion are connected to each other.

According to the configuration of [3], the portion functioning as a lens (first portion) and the portion outside the portion (second portion) can be visually and easily distinguished. In addition, if the optical member includes a shape in which the curved surface portions are connected to each other, the shape of a mold required to manufacture the optical member is complicated, and the shape of the boundary portion between the curved surface portions may be disturbed. Therefore, according to the configuration of [3], the optical member can be easily manufactured.

[4] The laser module according to any one of [1] to [3], wherein the second portion surrounds the first portion when viewed from the second direction.

According to the configuration of [4], by providing the second portion over the entire circumference of the outer edge portion of the first portion functioning as a lens, the support stability of the first portion can be improved. In addition, for example, in a case where the second portion of the optical member is attached to the support member by bonding or the like, stress (external force) related to bonding can be dispersed over the entire circumference of the outer edge portion of the first portion without concentrating the stress on one place of the outer edge portion of the first portion. As a result, it is possible to suppress local deformation of the first portion that degrades the lens function of the first portion.

[5] The laser module according to any one of [1] to [4], wherein
the second portion is directly supported by the support member, and
the first portion is not directly supported by the support member.

According to the configuration of [5], by directly supporting only the second portion that does not have a lens function by the support member, it is possible to prevent the first portion having a lens function from coming into contact with the support member and being damaged. As a result, the reliability of the laser module can be enhanced.

[6] The laser module according to any one of [1] to [5], wherein the optical member is formed of chalcogenide.

According to the configuration of [6], by using chalcogenide that can be relatively easily precision molded among materials that transmit mid-infrared light, the optical member having the first portion and the second portion can be easily and stably manufactured.

[7] The laser module according to any one of [1] to [6], wherein a surface of the optical member facing the quantum cascade laser element is not supported by the support member.

According to the configuration of [7], as compared to a case where the surface of the optical member facing the QCL element is supported by the support member, that is, a case where a part of the support member is disposed between the optical member and the QCL element, the surface of the optical member (particularly, the surface of the first portion functioning as a lens) can be easily disposed as close as possible to the first end face of the QCL element. As a result, most of the first light emitted from the first end face of the QCL element can easily pass through the lens portion (first portion) of the optical member. Therefore, it is possible to suitably increase the amount of the first light incident on the diffraction grating portion, and eventually improve the output of the laser module.

[8] The laser module according to [7], wherein
the support member includes
a first hole configured to be open to a side of the diffraction grating portion,
a second hole configured to include the first hole, be larger than the first hole, and be open to a side of the quantum cascade laser element when viewed from the second direction, and
a counterbore surface configured to connect the first hole and the second hole and extend along a plane intersecting the second direction,
the optical member is inserted into the second hole, and
at least a part of the second portion facing the diffraction grating portion is supported in surface contact with the counterbore surface.

According to the configuration of [8], by using the support member having the first hole, the second hole, and the counterbore surface to support the portion of the second portion facing the diffraction grating portion in surface contact with the counterbore surface, it is possible to stably support the optical member while implementing the configuration of [7].

[9] The laser module according to any one of [1] to [8], wherein the second portion is formed of a member different from the first portion.

According to the configuration of [9], the second portion that does not require optical design is formed of a member (for example, a metal or the like that is easily fixed to the support member) different from the first portion, so that the degree of freedom in designing the optical member can be increased, and the reliability of the laser module can be improved.

[10] The laser module according to any one of [1] to [9], wherein an area of the second portion is larger than an area of the first portion when viewed from the second direction.

According to the configuration of [10], by making the area of the second portion that can be used as a portion for supporting (holding) the optical member larger than the area of the lens portion (first portion), the degree of freedom in designing the structure for supporting the optical member can be improved.

[11] The laser module according to any one of [1] to [10], wherein
the optical member is disposed so as to cause, when the first light passes through a first surface of the first portion facing the diffraction grating portion, all of a beam width region of the first light to fall within the first surface, and
the beam width region of the first light is a region between two points at which intensity of the first light is 1/e² of peak intensity in the first direction.

According to the configuration of [11], the first light emitted from the first end face of the QCL element can be efficiently guided to the diffraction grating portion via the first portion.

[12] The laser module according to any one of [1] to [11], wherein
an antireflection film is formed on at least one of a surface facing the quantum cascade laser element or a surface facing the diffraction grating portion in the first portion and the second portion, and
when viewed from the second direction, an outer edge portion of the antireflection film is located inside an outer edge portion of the second portion.

According to the configuration of [12], by providing the antireflection film, it is possible to suppress the reflection of the first light and the second light on the surface of the first portion facing the quantum cascade laser element or the diffraction grating portion, and to suitably guide the first light to the diffraction grating portion and suitably guide the second light to the QCL element. In addition, the antireflection film is provided not only on the first portion but also on the second portion so as to reliably cover the first portion, but the outer edge portion of the antireflection film does not reach the outer edge portion of the second portion. Therefore, for example, in a case where the second portion is fixed (bonded) to the support member via an adhesive or the like, a part of the second portion not being provided with the antireflection film can be used as a bonding region. In addition, since the influence of bonding does not reach the antireflection film, peeling of the antireflection film can be suppressed. In addition, in a case where the antireflection film is provided so as to reach the outer edge portion of the second portion, a burr is generated in the process of forming the antireflection film, and the antireflection film may be easily peeled off starting from the burr. According to the configuration of [12], it is possible to suppress the generation of such burrs and to suppress the peeling of the antireflection film.

According to one aspect of the present disclosure, it is possible to provide a laser module capable of facilitating the support of the lens disposed between the QCL element and the diffraction grating portion while downsizing the laser module.

### BRIEF DESCRIPTION OF THE DRAWINGS

FIG. 1 is a perspective view of a laser module according to an embodiment;

FIG. 2 is a perspective cross-sectional view of the laser module of FIG. 1 at a central portion in the Y-axis direction;

FIG. 3 is a cross-sectional view of the laser module as viewed from the Y-axis direction in FIG. 2;

FIG. 4 is a front view of a MEMS diffraction grating;

FIG. 5 is a cross-sectional view of a diffraction grating portion taken along line V-V of FIG. 4;

FIG. 6 is a diagram illustrating a configuration of a first lens member;

FIG. 7 is a diagram illustrating a positional relationship between a QCL element, the first lens member, and the diffraction grating portion;

FIGS. 8A and 8B are diagrams illustrating measurement results of wavelengths and output of the laser modules according to a comparative example and an example; and

FIGS. 9A to 9C are diagrams illustrating first to third modifications of the first lens member.

### DETAILED DESCRIPTION

Hereinafter, an embodiment of the present disclosure will be described in detail with reference to the drawings. Note that, in the following description, identical or equivalent elements are denoted by identical reference numerals, and redundant description thereof will be omitted. In addition, words such as “upper” and “lower” are for convenience based on the state illustrated in the drawings.

### [Overall Configuration of Laser Module]

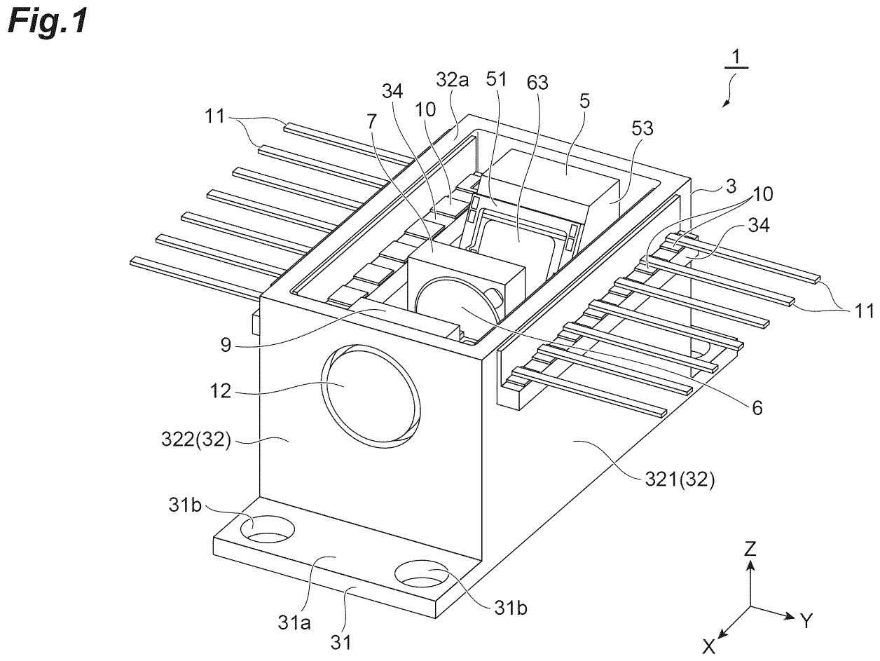

As illustrated in FIGS. 1 to 3, a laser module 1 includes a quantum cascade laser element (hereinafter, “QCL element”) 2 and a package 3 that airtightly houses the QCL element 2. The laser module 1 is a wavelength-tunable light source in which the wavelength of output light (laser light L) is made tunable. The laser module 1 can be used, for example, for biometric measurement such as glucose measurement and measurement of an absorption spectrum of an analysis target having a light absorption band such as VOC gas (a volatile organic compound). For example, when such an absorption spectrum is measured, the analysis target housed in a light transmissive container is disposed between the laser module 1 and a photodetector (not illustrated). The laser module 1 then changes the wavelength of the output light (the laser light L) at high speed to perform wavelength sweep in a predetermined wavelength range (for example, the mid-infrared region). As a result, the absorption spectrum is calculated on the basis of the detection result of the photodetector. Note that, the analysis target may be any of a gas, a liquid, and a solid.

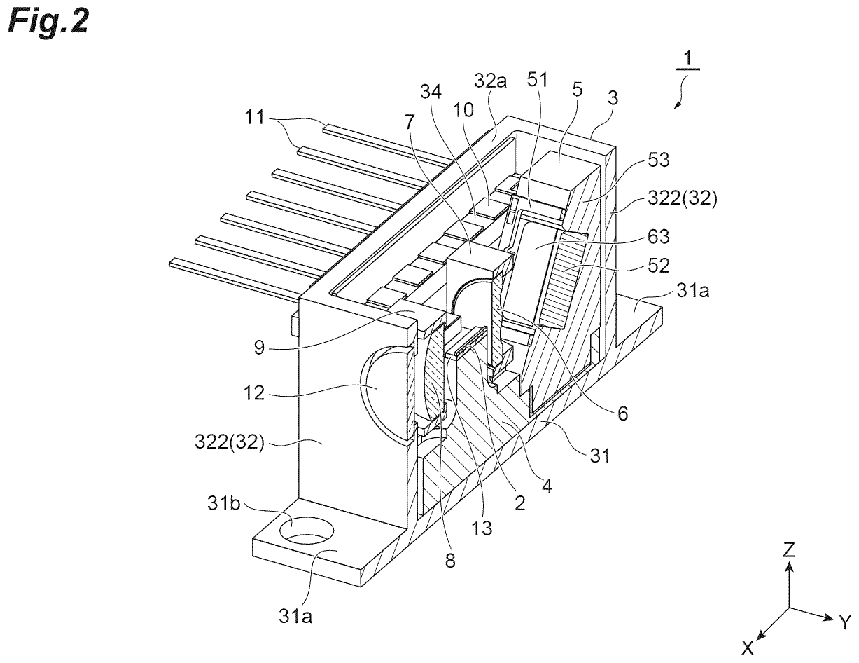

The package 3 is a housing that houses the QCL element 2, a mount member 4, a diffraction grating unit 5, a lens holder 7 (support member) that supports (holds) a lens member 6 (optical member, first lens member), and a lens holder 9 that supports (holds) a lens member 8 (second lens member). In the package 3, an optical path between the diffraction grating unit 5 (a diffraction grating portion 64) and an incident surface 8a of the lens member 8 is disposed. In the present embodiment, as an example, the package 3 is configured as a butterfly package. The package 3 includes a bottom wall 31, a side wall 32, and a top wall 33. In FIGS. 1 and 2, the top wall 33 of the package 3 is not illustrated.

The bottom wall 31 is a rectangular plate-shaped member. The bottom wall 31 is formed of, for example, a metal material such as copper tungsten. The bottom wall 31 is a base member on which the mount member 4 is mounted. In the present specification, for convenience, the longitudinal direction of the bottom wall 31 is represented as an X-axis direction (second direction), the lateral direction of the bottom wall 31 is represented as a Y-axis direction (third direction), and a direction perpendicular to the bottom wall 31 (that is, a direction orthogonal to both the X-axis direction and the Y-axis direction) is represented as a Z-axis direction (first direction). In the present embodiment, the X-axis direction is a direction (that is, a direction orthogonal to end faces 2a and 2b) in which the end faces 2a and 2b of the QCL element 2 to be described later face each other, and is also a direction (an optical axis direction) along the optical axis of the laser light L emitted from the QCL element 2.

The side wall 32 is provided upright on the bottom wall 31. The side wall 32 is formed in an annular shape (in the present embodiment, a rectangular annular shape) so as to surround the internal space in which the QCL element 2 and the like are housed when viewed from the Z-axis direction. In the present embodiment, the side wall 32 is formed in a rectangular tubular shape. The side wall 32 is formed of a metal material such as Kovar. The side wall 32 is, for example, a Kovar frame plated with Ni/Au. In the present embodiment, the side wall 32 is provided at the central portion in the longitudinal direction (the X-axis direction) of the bottom wall 31. The width of the side wall 32 along the lateral direction (the Y-axis direction) matches the width of the bottom wall 31 along the lateral direction, and the width of the side wall 32 along the longitudinal direction (the X-axis direction) is shorter than the width of the bottom wall 31 in the longitudinal direction. That is, on both sides in the longitudinal direction of the bottom wall 31, a projecting portion 31a that projects outward from the side wall 32 and extends is formed. Screw holes 31b for attaching the package 3 (the bottom wall 31) to other members are provided in portions corresponding to the four corners of the bottom wall 31 in the projecting portion 31a.

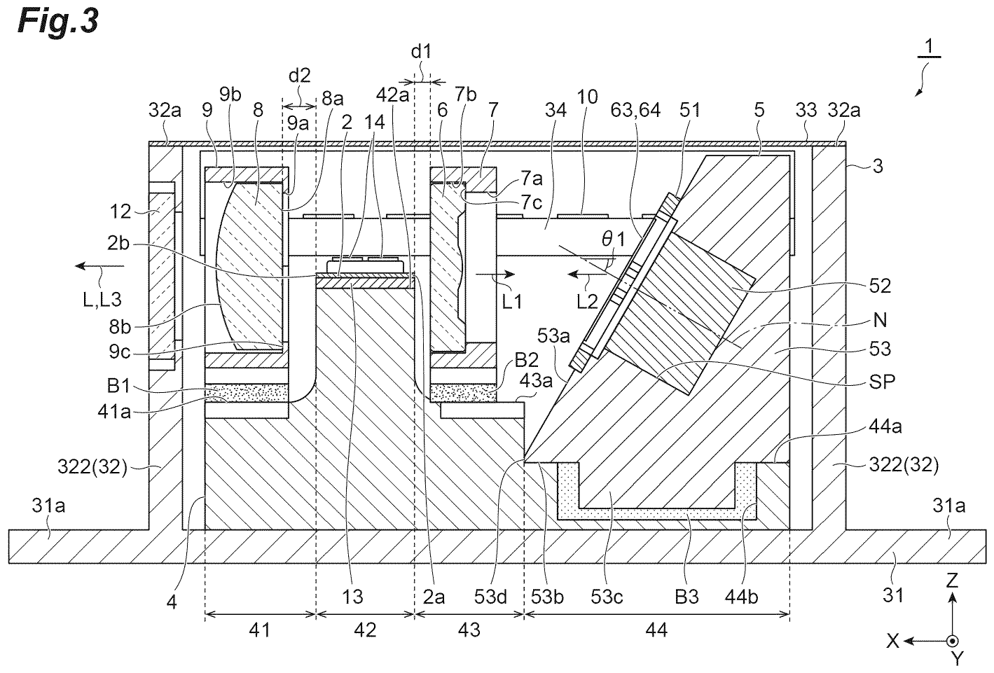

The top wall 33 (see FIG. 3) is a member that closes the opening of the side wall 32 on the opposite side to the side of the bottom wall 31. The top wall 33 has a rectangular plate shape. The outer shape (the width in the longitudinal direction and the lateral direction) of the top wall 33 viewed from the Z-axis direction substantially matches the outer shape of the side wall 32. The top wall 33 is formed of, for example, the same metal material (for example, Kovar or the like) as the side wall 32. The top wall 33 is joined to an end portion 32a of the side wall 32 on the opposite side to the side of the bottom wall 31 by seam welding or the like, for example, in a state where the inside of the package 3 is replaced with vacuum or nitrogen.

Each of paired first side walls 321 (that is, portions intersecting the lateral direction (the Y-axis direction)) extending along the longitudinal direction (the X-axis direction) in the side wall 32 includes a projecting wall 34 that projects both outside and inside the first side wall 321. The projecting wall 34 is an eaves member extending along the X-axis direction above (toward the top wall 33) the center position of the first side wall 321 in the Z-axis direction. On the upper surface of the projecting wall 34, a plurality of (in the present embodiment, a total of 14, that is, seven terminals for each projecting wall 34) flat plate-shaped electrode terminals 10 for supplying power to each member (for example, the QCL element 2, a movable diffraction grating 51 (a coil 65), and the like) in the package 3 are arranged. Each electrode terminal 10 penetrates the first side wall 321. As illustrated in FIG. 1, a portion of each electrode terminal 10 located outside the first side wall 321 is electrically connected to a lead pin 11 electrically connected to an external power supply. The electrode terminals 10 are arranged on the upper surface of the projecting wall 34 at substantially equal intervals along the X-axis direction. The lead pins 11 are arranged on portions of the electrode terminals 10 located outside the first side wall 321 at substantially equal intervals along the X-axis direction. A portion of each electrode terminal 10 located inside the first side wall 321 is electrically connected to each member in the package 3 via a wire (not illustrated) or the like. According to the above configuration, power is supplied from the external power supply to each member via a wire (not illustrated), the electrode terminal 10, and the lead pin 11.

A light exit window 12 through which the laser light L emitted from the one end face 2b of the QCL element 2 passes is provided on one of the second side walls 322 (that is, portions intersecting the longitudinal direction (the X-axis direction)) extending along the lateral direction (the Y-axis direction) in the side wall 32. The light exit window 12 is formed of, for example, a material (for example, germanium or the like) that transmits the laser light L with a wavelength in the mid-infrared region. In the present embodiment, as an example, the light exit window 12 is formed in a disk shape. The light exit window 12 is fixed to a circular opening formed in one of the second side walls 322.

Next, each member housed in the package 3 will be described. As illustrated in FIGS. 2 and 3, the QCL element 2, the diffraction grating unit 5, the lens holder 7, and the lens holder 9 are arranged on the bottom wall 31 via the mount member 4. The mount member 4 is fixed to the bottom wall 31 by, for example, joining or screwing. The mount member 4 is formed of a material with excellent thermal conductivity, such as copper. Note that, in the present embodiment, the mount member 4 is directly disposed on the bottom wall 31, but a cooling element such as a Peltier module may be disposed between the mount member 4 and the bottom wall 31. In addition, the mount member 4 is a single member in the present embodiment, but the mount member 4 may be a combination of a plurality of members (parts).

As illustrated in FIGS. 2 and 3, the mount member 4 is a member elongated in the X-axis direction. The QCL element 2, the diffraction grating unit 5, the lens holder 7, and the lens holder 9 are mounted on the mount member 4. The mount member 4 includes a first mounting portion 41, a second mounting portion 42, a third mounting portion 43, and a fourth mounting portion 44. The first mounting portion 41, the second mounting portion 42, the third mounting portion 43, and the fourth mounting portion 44 are arranged in order from the side of the lens holder 9 toward the side of the diffraction grating unit 5 along the X-axis direction. The lens holder 9 is mounted on the first mounting portion 41 via a bonding layer B1 formed of, for example, a photocurable resin (for example, a UV curable resin or the like). The QCL element 2 is mounted on the second mounting portion 42. The lens holder 7 is mounted on the third mounting portion 43 via a bonding layer B2 formed of, for example, a photocurable resin (for example, a UV curable resin or the like) similar to that for the bonding layer B1. The diffraction grating unit 5 is mounted on the fourth mounting portion 44. That is, the light exit window 12, the lens member 8, the QCL element 2, the lens member 6, and the diffraction grating unit 5 are arranged in this order along the X-axis direction.

The first mounting portion 41 and the third mounting portion 43 have the same thickness in the Z-axis direction. That is, when the bottom wall 31 is used as a reference, the height position of an upper surface 41a of the first mounting portion 41 matches the height position of an upper surface 43a of the third mounting portion 43. The lens holder 9 is adhesively fixed to the upper surface 41a of the first mounting portion 41 via the bonding layer B1. Similarly, the lens holder 7 is adhesively fixed to the upper surface 43a of the third mounting portion 43 via the bonding layer B2. The length of the lens holder 7 in the X-axis direction is, for example, about 2.2 mm.

It is preferable to use a photocurable resin as an adhesive (the bonding layers B1 and B2) for fixing the lens holders 7 and 9 to the mount member 4. The reason is as follows. When the lens holders 7 and 9 are fixed to the mount member 4, it is necessary to align the lens holders 7 and 9 (the lens members 6 and 8) in the XYZ directions. Therefore, the process of curing the adhesive is not performed in a state where the lens holders 7 and 9 are sufficiently pressed against the mount member 4. In such a case, the lens holders 7 and 9 can be bonded to the mount member 4 with higher positional accuracy by using the photocurable resin rather than using a thermosetting resin as the adhesive. A precision member such as the QCL element 2 is disposed between the lens holders 7 and 9. In a case where the thermosetting resin is used as the adhesive, the heat treatment for curing the adhesive may affect the quality of the QCL element 2. Because of the above reason, in the present embodiment, the lens holders 7 and 9 are fixed to the mount member 4 via the bonding layers B1 and B2 formed of the photocurable resin.

The second mounting portion 42 is provided between the first mounting portion 41 and the third mounting portion 43. The second mounting portion 42 is made thicker than the first mounting portion 41 and the third mounting portion 43 in the Z-axis direction. That is, an upper surface 42a of the second mounting portion 42 is at a position higher than the upper surface 41a of the first mounting portion 41 and the upper surface 43a of the third mounting portion 43. The QCL element 2 is fixed to the upper surface 42a of the second mounting portion 42 via a sub-mount 13. The sub-mount 13 is a rectangular plate-shaped member on which the QCL element 2 is placed. In the present embodiment, the QCL element 2 and the sub-mount 13 are arranged at the center position of the upper surface 42a in the Y-axis direction (the center position of the package 3 in the Y-axis direction). The sub-mount 13 is formed of a material (for example, aluminum nitride or the like) with a thermal expansion coefficient close to that of the QCL element 2. The QCL element 2 is joined to the sub-mount 13 via, for example, an AuSn-based solder material. Furthermore, the sub-mount 13 is joined to the mount member 4 (the upper surface 42a) via, for example, an In-based (InSn, InAg, or the like) solder material. As described above, since the QCL element 2 is integrated with the sub-mount 13, a combination of the QCL element 2 and the sub-mount 13 can be regarded as “QCL element”.

In addition to the sub-mount 13, an electrode pad 14, a temperature sensor (not illustrated), and the like are arranged on the upper surface 42a of the second mounting portion 42. The electrode pad 14, the temperature sensor, and the like are joined to the mount member 4 (the upper surface 42a) via, for example, a resin adhesive or the like. In the present embodiment, the electrode pad 14 relays the electrical connection between the electrode terminal 10 and the QCL element 2. In the present embodiment, two electrode pads 14 are provided on the upper surface 42a of the second mounting portion 42. Specifically, one electrode pad 14 electrically connected to the cathode (in the present embodiment, the upper surface (the mesa upper surface) of the QCL element 2) of the QCL element 2 and the other electrode pad 14 electrically connected to the anode (for example, the sub-mount 13) of the QCL element 2 are provided on the upper surface 42a of the second mounting portion 42.

The fourth mounting portion 44 is made thinner than the first mounting portion 41 and the third mounting portion 43. That is, an upper surface 44a of the fourth mounting portion 44 is at a position lower than the upper surface 41a of the first mounting portion 41 and the upper surface 43a of the third mounting portion 43. An arrangement hole 44b (hole) is formed in the fourth mounting portion 44. As illustrated in FIG. 3, the diffraction grating unit 5 is fixed to the fourth mounting portion 44 using a resin adhesive B3 such as a thermosetting resin in a state where a projecting portion 53c, which is a part of a yoke 53 to be described later, is inserted into the arrangement hole 44b.

The QCL element 2 has the end face 2a (first end face) and the end face 2b (second end face) facing each other in the X-axis direction (second direction). The end face 2a is a surface facing the lens member 6, and the end face 2b is a surface facing the lens member 8. The QCL element 2 emits light in the mid-infrared region (for example, 4 μm to 12 μm) from each of the end faces 2a and 2b. The end faces 2a and 2b are flat surfaces (cleavage planes) perpendicular to the X-axis direction, and the optical axis of the laser light L emitted from the QCL element 2 is along the X-axis direction. The QCL element 2 has, for example, a stacked structure including an active layer including a plurality of quantum well layers (for example, InGaAs) and a plurality of quantum barrier layers (for example, InAlAs) and paired cladding layers (for example, InP) arranged on both sides of the active layer with the active layer interposed therebetween. In the present embodiment, the stacking direction of the stacked structure matches the Z-axis direction. Note that the QCL element 2 may include a plurality of active layers having different center wavelengths and a pair of cladding layers, and even in this case, the QCL element 2 can emit broadband light as described above. A non-reflective coating may be applied on the end face 2a, and a low reflective coating may be applied on the end face 2b functioning as a resonance surface.

The lens member 8 is disposed on the side of the QCL element 2 opposite to the side on which the movable diffraction grating 51 (the diffraction grating unit 5) is located. That is, the lens member 8 is disposed at a position facing the end face 2b of QCL element 2. The lens member 8 is, for example, an aspherical lens formed of zinc selenide (ZnSe). A non-reflective coating may be applied on the surface of the lens member 8. The lens member 8 allows light L3 (third light) emitted from the QCL element 2 (the end face 2b) to pass therethrough. For example, the lens member 8 collimates the light L3. The light L3 collimated by the lens member 8 passes through the light exit window 12 and is output to the outside as output light (the laser light L).

The lens member 6 is disposed between the end face 2a of the QCL element 2 and the movable diffraction grating 51 (the diffraction grating unit 5). That is, the lens member 6 is disposed at a position facing the end face 2a of the QCL element 2. The lens member 6 allows the light L1 (first light) emitted from the end face 2a of the QCL element 2 and the light L2 (second light) returning from the movable diffraction grating 51 to the QCL element 2 to pass therethrough. For example, the lens member 6 collimates the light L1.

The lens holders 7 and 9 each have a substantially rectangular parallelepiped outer shape. The lens members 6 and 8 are supported (held) by the lens holders 7 and 9 with a resin adhesive or the like. The surfaces of the lens holders 7 and 9 are blackened by, for example, an alumite treatment or the like. Details of the support structure (the holding structure) of the lens members 6 and 8 by the lens holders 7 and 9 will be described later.

The diffraction grating unit 5 includes the movable diffraction grating 51, a magnet 52, and the yoke 53. The movable diffraction grating 51 is formed in a substantially plate shape. The magnet 52 is disposed on the side of the movable diffraction grating 51 opposite to the QCL element 2. The movable diffraction grating 51 is fixed to the yoke 53, and the magnet 52 is housed in the yoke 53. The movable diffraction grating 51, the magnet 52, and the yoke 53 are integrated to constitute one unit.

The light L1 collimated by the lens member 6 is incident on the movable diffraction grating 51 of the diffraction grating unit 5. The movable diffraction grating 51 diffracts and reflects the incident light L1 to return a part of the light L1 (the light L2 with a specific wavelength) to the end face 2a of the QCL element 2 via the lens member 6. That is, the movable diffraction grating 51 constitutes an external resonator for the light L1 emitted from the end face 2a of the QCL element 2. In the present embodiment, the movable diffraction grating 51 and the end face 2b of the QCL element 2 constitute a Littrow external resonator. As a result, the laser module 1 can amplify the light L2 with a specific wavelength and output the amplified light L2 to the outside as output light (the laser light L).

In addition, in the movable diffraction grating 51, the direction of the diffraction grating portion 64 that diffracts and reflects the incident light L1 can be changed at high speed. As a result, the wavelength of the light L2 returning from the movable diffraction grating 51 to the end face 2a of the QCL element 2 is tunable, and the wavelength of the output light (the laser light L) of the laser module 1 is tunable accordingly. By changing the wavelength of the laser light L, for example, wavelength sweep can be performed within the range of the gain band of the QCL element 2.

### (Detailed Configuration of Diffraction Grating Unit)

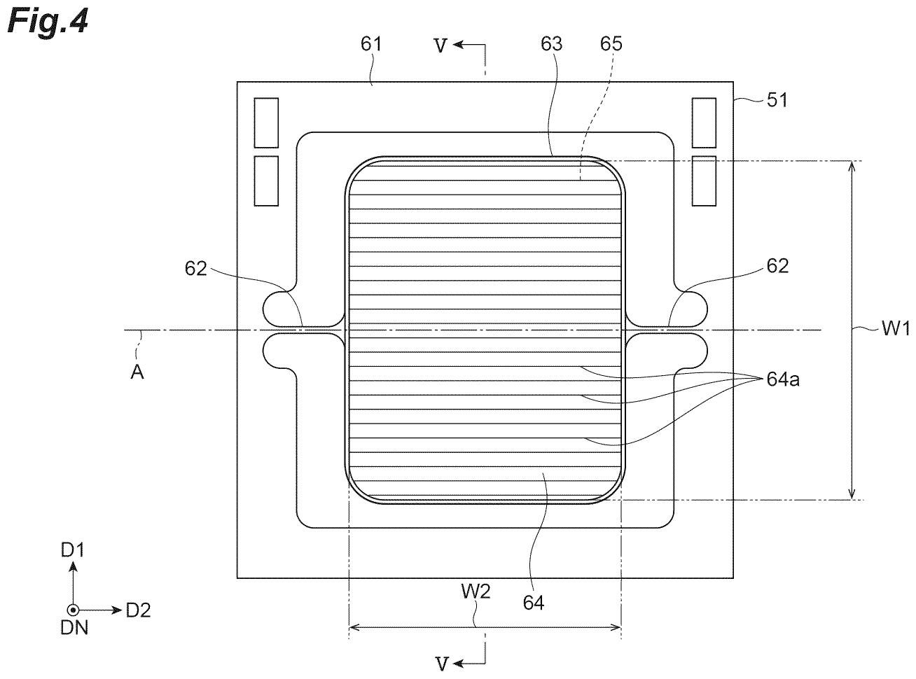

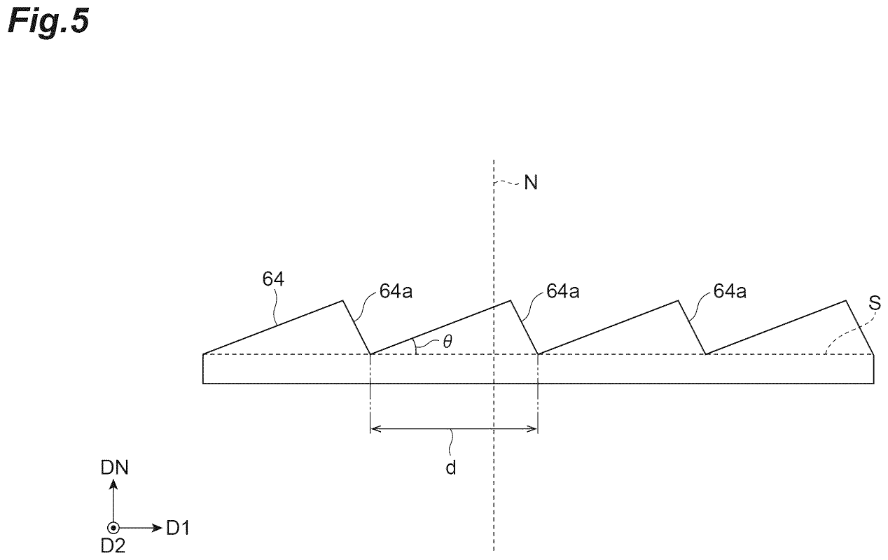

As illustrated in FIGS. 4 and 5, the movable diffraction grating 51 includes a support portion 61, a pair of coupling portions 62, a movable portion 63, the diffraction grating portion 64, and the coil 65. The movable diffraction grating 51 is configured as a MEMS device that causes the movable portion 63 to swing around an axis A. The MEMS device is a device formed using microfabrication technology called MEMS technology (patterning, etching, and the like), and includes a semiconductor device formed using semiconductor microfabrication technology.

The support portion 61 is a flat plate-shaped frame body with a rectangular shape in plan view. The support portion 61 supports the movable portion 63 via a pair of coupling portions 62. Each of the coupling portions 62 is a flat plate-shaped member with a rectangular rod shape in plan view, and extends along the axis A. Each coupling portion 62 couples the movable portion 63 to the support portion 61 on the axis A in such a manner that the movable portion 63 is swingable around the axis A.

The movable portion 63 is located inside the support portion 61. The movable portion 63 is swingable around the axis A as described above. The movable portion 63 is a flat plate-shaped member with a substantially rectangular shape in plan view. In the present embodiment, as an example, four corners of the movable portion 63 are chamfered in a rounded shape. That is, the four corners of the movable portion 63 are curved in an arc shape in plan view. As a result, the moment of inertia of the movable portion 63 can be reduced, and the movable portion 63 can swing at high speed. In this example, the movable portion 63 is formed in a substantially rectangular shape whose long side is parallel to a direction D1 (a direction orthogonal to the axis A) (fourth direction), and the length of the movable portion 63 in the direction D1 is longer than the length of the movable portion 63 in a direction D2 (a direction parallel to the axis A) (fifth direction). As an example, the length of the support portion 61 in the direction D1 is about 6 to 7 mm, and the length of the support portion 61 in the direction D2 is about 6 mm. In addition, the length of the movable portion 63 in the direction D1 is about 5 mm, the length of the movable portion 63 in the direction D2 is about 4 mm, and the thickness of the movable portion 63 is about 30 μm. The support portion 61, the coupling portion 62, and the movable portion 63 are integrally formed by being built in, for example, one silicon on insulator (SOI) substrate.

The diffraction grating portion 64 is provided on the surface of the movable portion 63 on the side of the QCL element 2. The diffraction grating portion 64 has a plurality of grating grooves 64a, and diffracts and reflects the light L1 emitted from the QCL element 2. The diffraction grating portion 64 includes, for example, a resin layer provided on the surface of the movable portion 63 and on which a diffraction grating pattern is formed, and a metal layer provided over the surface of the resin layer along the diffraction grating pattern. Alternatively, the diffraction grating portion 64 may include only a metal layer which is provided on the movable portion 63 and on which a diffraction grating pattern is formed. As the diffraction grating pattern, for example, in addition to a blazed grating with a sawtooth cross-section as in the present embodiment, a binary grating with a rectangular cross-section, a holographic grating with a sinusoidal cross-section, or the like can be used. The diffraction grating pattern is formed on the resin layer by, for example, a nanoimprint lithography method. The metal layer is, for example, a metal reflection film formed of gold, and is formed by vapor deposition.

As illustrated in FIG. 5, the plurality of grating grooves 64a are arranged at equal intervals in the direction D1. Each grating groove 64a extends straight in the direction D2. The repetition period (the distance between adjacent grating grooves 64a) d of the grating groove 64a in the direction D1 is, for example, 4 μm to 13 μm. The angle (the blazed angle) θ of the grating groove 64a with respect to a normal direction DN parallel to a normal line (a straight line perpendicular to a grating surface S) N of the diffraction grating portion 64 is, for example, 20 degrees to 35 degrees.

The diffraction grating portion 64 is formed to be slightly smaller than the movable portion 63 in plan view, and the outer edge of the diffraction grating portion 64 extends along the outer edge of the movable portion 63 at a constant interval from the outer edge of the movable portion 63. In this example, the diffraction grating portion 64 is formed in a substantially rectangular shape similar to the movable portion 63 in plan view. That is, the diffraction grating portion 64 is formed in a substantially rectangular shape whose long sides are parallel to the direction D1, and the length W1 of the diffraction grating portion 64 in the direction D1 is longer than the length W2 of the diffraction grating portion 64 in the direction D2. As described above, since the length W1 of the diffraction grating portion 64 in the direction D1 is long, the light L1 from the QCL element 2 can be successfully received by the diffraction grating portion 64 even in a case where the diffraction grating portion 64 is disposed in an inclined manner as illustrated in FIG. 3. In addition, since the length W2 of the diffraction grating portion 64 in the direction D2 is reduced, the laser module 1 can be downsized, and an increase in power consumption can be suppressed by suppressing an increase in size of the diffraction grating portion 64. As will be described later, the beam width in the Z-axis direction of the light L1 emitted from the QCL element 2 is longer than the beam width in the Y-axis direction. Therefore, by increasing the length W1 of the diffraction grating portion 64 in the direction D1 that is the direction along the Z-axis direction when viewed from the X-axis direction, the light L1 diffused in the Z-axis direction can be suitably incident on the diffraction grating portion 64, and unnecessary regions (that is, regions where the light L1 is not incident) of the diffraction grating portion 64 on both sides in the Y-axis direction can be reduced.

The coil 65 is formed of, for example, a metal material such as copper, and has a damascene structure embedded in a groove formed in the surface of the movable portion 63. The coil 65 is a drive coil that applies a current for driving the movable diffraction grating 51 (that is, for swinging the movable portion 63).

The magnet 52 generates a magnetic field (magnetic force) acting on the coil 65. The magnet 52 is, for example, a neodymium magnet (a permanent magnet) formed in a substantially rectangular parallelepiped shape.

The yoke 53 amplifies the magnetic force of the magnet 52 and forms a magnetic circuit together with the magnet 52. The surface of the yoke 53 is blackened by, for example, zinc plating. The yoke 53 has an inclined surface 53a, a lower surface 53b, the projecting portion 53c, and a positioning surface 53d.

The inclined surface 53a is inclined with respect to the end face 2a of the QCL element 2. By fixing the movable diffraction grating 51 on such an inclined surface 53a, the normal line N of the diffraction grating portion 64 of the movable diffraction grating 51 can be inclined with respect to the end face 2a. In this example, the diffraction grating portion 64 is inclined so as to face one side (the side of the top wall 33) in the Z-axis direction, but the diffraction grating portion 64 may be inclined so as to face the other side (the side of the bottom wall 31) in the Z-axis direction. The inclination angle (that is, the angle θ₁ of the normal line N with respect to the X-axis direction when viewed from the Y-axis direction) of the inclined surface 53a is set based on the oscillation wavelength of the QCL element 2, the number of grating grooves in the diffraction grating portion 64, a blazed angle, and the like. For example, in a case where the oscillation wavelength is in the band of 7 μm and the number of grooves is 150/mm, the angle θ₁ is set to about 30 degrees.

The yoke 53 is formed in a substantially U shape (an inverted C shape) when viewed from the Y-axis direction, and defines an arrangement space SP opened to the inclined surface 53a. The magnet 52 is disposed in the arrangement space SP, and the magnet 52 is housed in the yoke 53. The yoke 53 surrounds magnet 52 when viewed from the Y-axis direction. The movable diffraction grating 51 is fixed to the inclined surface 53a at the edge of the support portion 61 so as to cover the opening of the arrangement space SP.

The lower surface 53b is a surface facing the upper surface 44a of the fourth mounting portion 44. The lower surface 53b includes the projecting portion 53c that projects downward. The positioning surface 53d is a surface intersecting with the X axis direction so as to connect the inclined surface 53a and the lower surface 53b. In the present embodiment, the positioning surface 53d is orthogonal to the X-axis direction. The positioning surface 53d is in contact with the side surface of the third mounting portion 43 (the surface orthogonal to the X-axis direction and connecting the upper surface 43a of the third mounting portion 43 and the upper surface 44a of the fourth mounting portion 44). As a result, the diffraction grating unit 5 is positioned in the X-axis direction.

In the movable diffraction grating 51, when a current flows through the coil 65, Lorentz force is generated in a predetermined direction in electrons flowing through the coil 65 by a magnetic field formed by the magnet 52 and the yoke 53. As a result, the coil 65 receives force in a predetermined direction. Therefore, by controlling the direction, the magnitude, or the like of the current flowing through the coil 65, the movable portion 63 (the diffraction grating portion 64) can be swung around the axis A. In addition, by causing a current with a frequency corresponding to the resonance frequency of the movable portion 63 to flow through the coil 65, the movable portion 63 can be swung at a resonance frequency level (for example, at a frequency of 1 kHz or more) at high speed. As described above, the coil 65, the magnet 52, and the yoke 53 function as an actuator unit that causes the movable portion 63 to swing.

### (Detailed Configuration of First Lens Member)

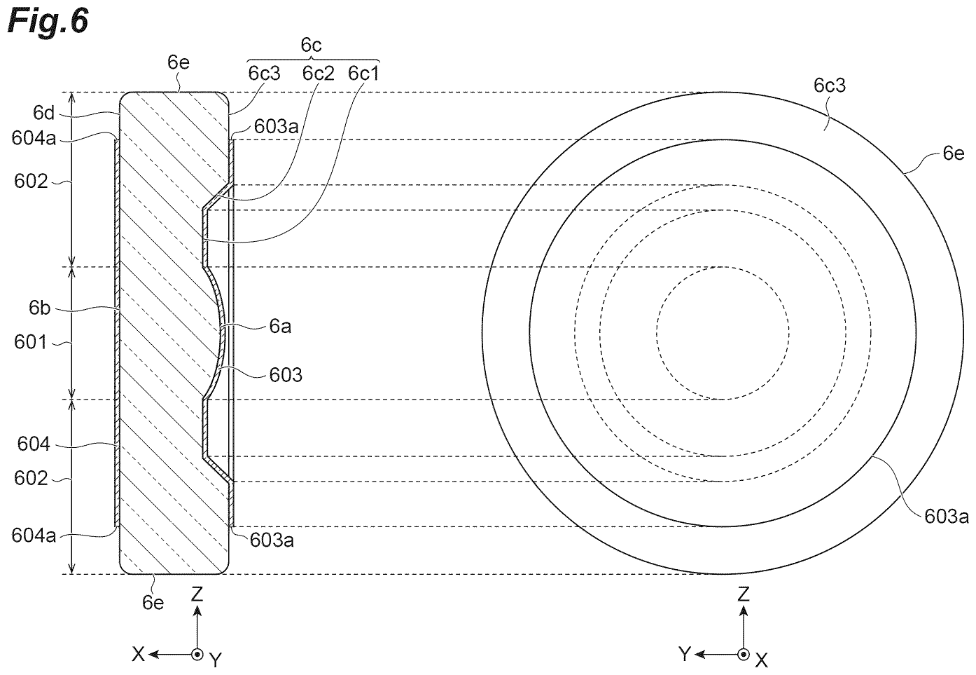

The configuration of the lens member 6 (the first lens member) will be described in detail with reference to FIG. 6. The left part of FIG. 6 is a cross-sectional view of the lens member 6 at the central portion in the Y-axis direction. The right part of FIG. 6 is a plan view of the lens member 6 as viewed from the side of the diffraction grating unit 5 along the X-axis direction. As illustrated in FIG. 6, the lens member 6 has a substantially disk-like outer shape as a whole. The lens member 6 includes a first portion 601 (lens portion) and a second portion 602. In the present embodiment, the lens member 6 is formed of chalcogenide (chalcogenide glass). As a result, by using chalcogenide that can be relatively easily precision molded among materials that transmit mid-infrared light, the lens member 6 having the first portion 601 and the second portion 602 can be easily and stably manufactured. More specifically, even in a complicated shape in which the first portion 601 and the second portion 602 are integrated, the lens member 6 can be manufactured with low cost by molding, and thus a high cost reduction effect can be obtained particularly in the mass production of the lens member 6.

The first portion 601 is a portion constituting a collimator lens that collimates the light L1 emitted from the end face 2a of the QCL element 2. In the present embodiment, the first portion 601 is a short focal length microlens with a diameter of several mm or less. The first portion 601 is a substantially columnar portion formed in the central portion of the lens member 6 when viewed from the X-axis direction. The first portion 601 includes a first surface 6a and a second surface 6b.

The first surface 6a is a surface facing the diffraction grating unit 5 (the diffraction grating portion 64), and is formed in a curved surface shape protruding toward the diffraction grating portion 64. The second surface 6b is a surface facing the end face 2a of the QCL element 2, and is formed in a planar shape.

The second portion 602 is a portion that is connected to the outer edge portion of the first portion 601 when viewed from the X-axis direction and does not constitute a collimator lens. That is, the second portion 602 does not play a role of collimating the light L1 in the lens member 6, and mainly plays a role of being supported by the lens holder 7 as described later. When viewed from the X-axis direction, the second portion 602 surrounds the first portion 601. In the present embodiment, when viewed from the X-axis direction, the second portion 602 is formed in an annular shape around the first portion 601. According to the above configuration, by providing the second portion 602 over the entire circumference of the outer edge portion of the first portion 601 functioning as a lens, the support stability of the first portion 601 can be improved. In addition, for example, in a case where the second portion 602 of the lens member 6 is attached to the lens holder 7 by bonding or the like, stress (external force) related to bonding can be dispersed over the entire circumference of the outer edge portion of the first portion 601 without concentrating the stress on one place of the outer edge portion of the first portion 601. As a result, it is possible to suppress local deformation of the first portion 601 that degrades the lens function of the first portion 601. The second portion 602 includes a third surface 6c and a fourth surface 6d.

The third surface 6c is a surface facing the diffraction grating unit 5 (the diffraction grating portion 64), and includes an inner flat surface 6cl, an inclined surface 6c2, and an outer flat surface 6c3. The inner flat surface 6cl is a planar portion connected to the outer edge portion of the first surface 6a of the first portion 601 when viewed from the X-axis direction, and is, as an example, along a plane (a YZ plane) orthogonal to the X-axis direction in the present embodiment. The outer flat surface 6c3 is a planar portion located closer to the side of the diffraction grating portion 64 than the inner flat surface 6cl, and is, as an example, along the plane (the YZ plane) orthogonal to the X-axis direction in the present embodiment. The inclined surface 6c2 is a planar portion connecting the outer edge portion of the inner flat surface 6cl and the inner edge portion of the outer flat surface 6c3. When viewed from the Y-axis direction, the inclined surface 6c2 is inclined with respect to the Z-axis direction. More specifically, the inclined surface 6c2 is inclined so as to be away from the fourth surface 6d toward the outside from the central portion of the lens member 6 along the Z-axis direction. The outer flat surface 6c3 is located closer to the side of the diffraction grating portion 64 than the central portion (a portion located closest to the side of the diffraction grating portion 64) of the first surface 6a of the first portion 601. That is, in the present embodiment, the first portion 601 constituting the collimator lens is surrounded by an annular wall portion constituted by the inclined surface 6c2 and the outer flat surface 6c3.

The fourth surface 6d is a surface facing the end face 2a of the QCL element 2, and is a surface having a planar portion connected to the outer edge portion of the second surface 6b of the first portion 601 when viewed from the X-axis direction. In the present embodiment, the entire fourth surface 6d is configured as a flat surface continuous (flush) with the second surface 6b.

As described above, the first surface 6a of the first portion 601 is formed in a curved surface shape, and the inner flat surface 6cl of the second portion 602 is formed in a flat surface shape. As a result, at the boundary portion between the first portion 601 and the second portion 602 on the side of the lens member 6 on which the diffraction grating portion 64 is located, the curved surface portion (that is, the first surface 6a) included in the first portion 601 and the planar portion (that is, the inner flat surface 6cl) included in the second portion 602 are connected to each other. That is, the curvature of the surface of the lens member 6 facing the diffraction grating portion 64 changes with the boundary portion between the first portion 601 and the second portion 602 on the side of the diffraction grating portion 64 as a boundary. According to the above configuration, the portion functioning as a lens (the first portion 601) and the portion outside the portion (the second portion 602) can be visually and easily distinguished. In addition, if the lens member 6 includes a shape in which the curved surface portions are connected to each other, the shape of a mold required to manufacture the lens member 6 is complicated, and the shape of the boundary portion between the curved surface portions may be disturbed. Therefore, according to the above configuration, the lens member 6 can be easily manufactured.

An antireflection film is formed on at least one (both in the present embodiment) of a surface facing the QCL element 2 (that is, the second surface 6b and the fourth surface 6d) or a surface facing the diffraction grating portion 64 (that is, the first surface 6a and the third surface 6c) in the first portion 601 and the second portion 602. In the present embodiment, an antireflection film 603 is formed on the first surface 6a and the third surface 6c, and an antireflection film 604 is formed on the second surface 6b and the fourth surface 6d. The antireflection films 603 and 604 are formed of, for example, a multilayer film using a fluoride such as YF₃, CeF₃, or BaF₂, a sulfide such as ZnS or ZnSe, a high refractive index material such as Si or Ge, or the like. When viewed from the X-axis direction, outer edge portions 603a and 604a of the antireflection films 603 and 604 are located inside the outer edge portion of the second portion 602 (that is, a side surface 6e of the lens member 6). In the present embodiment, the outer edge portion 603a of the antireflection film 603 is located on the outer flat surface 6c3. As a result, the annular peripheral edge portion of the second portion 602 (the peripheral edge portion of the outer flat surface 6c3) is exposed. By providing the antireflection films 603 and 604 as described above, it is possible to suppress the reflection of the light L1 and the light L2 on the first surface 6a or the second surface 6b of the first portion 601, and to suitably guide the light L1 to the diffraction grating portion 64 and suitably guide the light L2 to the QCL element 2. In addition, the antireflection films 603 and 604 are provided not only on the first portion 601 but also on the second portion 602 so as to reliably cover the first portion 601, but the outer edge portions 603a and 604a of the antireflection films 603 and 604 do not reach the outer edge portion (the side surface 6e) of the second portion 602. Therefore, for example, in a case where the second portion 602 is fixed (bonded) to the lens holder 7 via an adhesive or the like as described later, a part (in the present embodiment, a part of the outer flat surface 6c3) of the second portion 602 not including the antireflection films 603 and 604 can be used as a bonding region. In addition, since the influence of bonding of the lens member 6 to the lens holder 7 does not reach the antireflection films 603 and 604, peeling of the antireflection films 603 and 604 can be suppressed. In addition, in a case where the antireflection films 603 and 604 are provided so as to reach the outer edge portion (the side surface 6e) of the second portion 602, a burr is generated in the vicinity of the outer edge portion in the process of forming the antireflection films 603 and 604, and the antireflection films 603 and 604 may be easily peeled off starting from the burr. As described above, according to the configuration in which the outer edge portions 603a and 604a of the antireflection films 603 and 604 are provided inside the outer edge portion of the second portion 602, it is possible to suppress the generation of such burrs and to suppress the peeling of the antireflection films 603 and 604.

In the present embodiment, as an example, the diameter of the entire lens member 6 (a portion combining the first portion 601 and the second portion 602) is 5 mm, and the diameter of the first portion 601 functioning as a collimator lens is 1.4 mm. The length from the top (the center) of the first surface 6a to the second surface 6b in the X-axis direction is 1 mm, and the length from the outer flat surface 6c3 to the fourth surface 6d in the X-axis direction is 1.1 mm.

As illustrated in the right part of FIG. 6, when viewed from the X-axis direction, the area of the second portion 602 (in the present embodiment, the area of the annular region excluding the circular region in the central portion) is larger than the area of the first portion 601 (in the present embodiment, the area of the circular region in the central portion). According to the above configuration, by making the area of the second portion 602 that can be used as a portion for supporting (holding) the lens member 6 larger than the area of the lens portion (the first portion 601), the degree of freedom in designing the structure for supporting the lens member 6 can be improved. In addition, since the handleability of the lens member 6 can be improved by enlarging the second portion 602 for holding the lens member 6, it is possible to reduce the risk of damage to the lens member 6 (particularly, the first portion 601 which is a lens portion) due to a handling error. In addition, since the distance from the portion where the second portion 602 is bonded to the lens holder 7 to the first portion 601 can be held, the risk that the adhesive flows into the first portion 601 can be reduced. Furthermore, it is possible to reduce the influence of the adhesion stress generated by bonding the lens holder 7 to the second portion 602 on the first portion 601.

### (Support Structure of First Lens Member)

An example of a support structure (a holding structure) of the lens member 6 (the first lens member) by the lens holder 7 will be described with reference to FIG. 3. In the present embodiment, the second portion 602 of the lens member 6 is directly supported (held) by the lens holder 7, and the first portion 601 of the lens member 6 is not directly supported (held) by the lens holder 7. More specifically, the first portion 601 is not in direct contact with the lens holder 7, and is not in indirect contact with the lens holder 7 via an adhesive or the like. According to the above configuration, by directly supporting only the second portion 602 that does not have a lens function by the lens holder 7, it is possible to prevent the first portion 601 having a lens function from coming into contact with the lens holder 7 and being damaged. As a result, the reliability of the laser module 1 can be enhanced. In addition, since the lens holder 7 does not come into contact with the first portion 601, a part of the light L1 passing through the first portion 601 can be prevented from being blocked by the lens holder 7.

Furthermore, the surface (in the present embodiment, the second surface 6b and the fourth surface 6d) of the lens member 6 facing the QCL element 2 is not supported by the lens holder 7. That is, the second surface 6b and the fourth surface 6d are not in direct contact with the lens holder 7, and are not in indirect contact with the lens holder 7 via an adhesive or the like. According to the above configuration, as compared to a case where the surface of the lens member 6 facing the QCL element 2 is supported by the lens holder 7, that is, a case where a part of the lens holder 7 is disposed between the surface of the lens member 6 facing the QCL element 2 (the second surface 6b and the fourth surface 6d) and the QCL element 2, the surface of the lens member 6 (particularly, the second surface 6b of the first portion 601 functioning as a lens) can be easily disposed as close as possible to the end face 2a of the QCL element 2. As a result, most of the light L1 emitted from the end face 2a of the QCL element 2 can easily pass through the lens portion (the first portion 601) of the lens member 6. Therefore, it is possible to suitably increase the amount of the light L1 incident on the diffraction grating portion 64, and eventually improve the output of the laser module 1.

In the present embodiment, as an example, in order to implement the support structure described above, the lens holder 7 has a substantially rectangular parallelepiped outer shape. In addition, the lens holder 7 includes a small-diameter hole 7a (first hole), a large-diameter hole 7b (second hole), and a counterbore surface 7c. The small-diameter hole 7a opens to the side of the diffraction grating portion 64 in the optical axis direction of the lens member 6 (the X-axis direction). The large-diameter hole 7b opens to the side of the QCL element 2 in the X-axis direction. The large-diameter hole 7b includes the small-diameter hole 7a and has a shape larger than the small-diameter hole 7a when viewed from the X-axis direction. When viewed from the X-axis direction, each of the small-diameter hole 7a and the large-diameter hole 7b is formed in a circular shape, and the diameter of the large-diameter hole 7b is larger than the diameter of the small-diameter hole 7a. As an example, the central axis of the small-diameter hole 7a and the central axis of the large-diameter hole 7b substantially match the optical axis of the lens member 6. The counterbore surface 7c is an annular surface that connects the small-diameter hole 7a and the large-diameter hole 7b and extends along a plane intersecting the X-axis direction. More specifically, the counterbore surface 7c connects an end portion of the small-diameter hole 7a on the side of the large-diameter hole 7b and an end portion of the large-diameter hole 7b on the side of the small-diameter hole 7a.

The lens member 6 is inserted into the large-diameter hole 7b. At least a part of the second portion 602 of the lens member 6 facing the diffraction grating portion 64 (in the present embodiment, a portion of the outer flat surface 6c3 not being provided with the antireflection film 603) is supported in surface contact with the counterbore surface 7c. As an example, the peripheral edge portion of the second portion 602 (the portion of the outer flat surface 6c3 not being provided with the antireflection film 603) is fixed to the counterbore surface 7c with, for example, a resin adhesive or the like. Alternatively, the lens member 6 may be fixed to the lens holder 7 by joining the side surface 6e of the lens member 6 and the inner surface of the large-diameter hole 7b with a resin adhesive or the like. According to the above configuration, the lens holder 7 having the small-diameter hole 7a, the large-diameter hole 7b, and the counterbore surface 7c is used to support the portion of the second portion 602 facing the diffraction grating portion 64 (in the present embodiment, a part of the outer flat surface 6c3 of the third surface 6c) in surface contact with the counterbore surface 7c, so that it is possible to stably support the lens member 6 while implementing the configuration in which a part of the lens holder 7 is not disposed between the lens member 6 and the QCL element 2 as described above.

### (Support Structure of Second Lens Member)

An example of a support structure (a holding structure) of the lens member 8 (the second lens member) by the lens holder 9 will be described with reference to FIG. 3. The lens member 8 has the incident surface 8a on which the light L3 emitted from the end face 2b of the QCL element 2 is incident, and an emission surface 8b that emits the light L3 passing through the inside of the lens member 8 toward the light exit window 12. As an example, the incident surface 8a is a planar surface facing the end face 2b of the QCL element 2, and the emission surface 8b is a curved surface facing the light exit window 12. The incident surface 8a and the emission surface 8b may be provided with an antireflection film similar to the antireflection films 603 and 604.

As an example, the lens holder 9 has a substantially rectangular parallelepiped outer shape. In addition, the lens holder 9 includes a small-diameter hole 9a, a large-diameter hole 9b, and a counterbore surface 9c. The small-diameter hole 9a opens to the side of the diffraction grating portion 64 in the optical axis direction of the lens member 8 (the X-axis direction). The large-diameter hole 9b opens to the side of the light exit window 12 in the X-axis direction. The large-diameter hole 9b includes the small-diameter hole 9a and has a shape larger than the small-diameter hole 9a when viewed from the X-axis direction. When viewed from the X-axis direction, each of the small-diameter hole 9a and the large-diameter hole 9b is formed in a circular shape, and the diameter of the large-diameter hole 9b is larger than the diameter of the small-diameter hole 9a. As an example, the central axis of the small-diameter hole 9a and the central axis of the large-diameter hole 9b substantially match the optical axis of the lens member 8. The counterbore surface 9c is an annular surface that connects the small-diameter hole 9a and the large-diameter hole 9b and extends along a surface intersecting the X-axis direction. More specifically, the counterbore surface 9c connects an end portion of the small-diameter hole 9a on the side of the large-diameter hole 9b and an end portion of the large-diameter hole 9b on the side of the small-diameter hole 9a. The lens member 8 is inserted into the large-diameter hole 9b. In addition, the peripheral edge portion of the incident surface 8a of the lens member 8 is supported in surface contact with the counterbore surface 9c. As an example, the peripheral edge portion of the incident surface 8a is fixed to the counterbore surface 9c by, for example, a resin adhesive or the like. Alternatively, the lens member 8 may be fixed to the lens holder 9 by joining the side surface of the lens member 8 (a surface facing the inner surface of the large-diameter hole 9b) and the inner surface of the large-diameter hole 9b with a resin adhesive or the like.

As described above, in the present embodiment, the counterbore surface 9c of the lens holder 9 supporting the lens member 8 is provided between the lens member 8 and the QCL element 2 (the end face 2b), whereas the counterbore surface 7c of the lens holder 7 supporting the lens member 6 is provided on the side of the lens member 6 opposite to the side on which the QCL element 2 (the end face 2a) is located. According to the above configuration, since a part of the lens holder 7 is not interposed between the lens member 6 and the QCL element 2, that is, a part of the lens holder 7 does not interfere when the second surface 6b and the end face 2a are brought close to each other, the second surface 6b and the end face 2a can be brought close to each other as much as possible. On the other hand, in the lens member 8, since the counterbore surface 9c is interposed between the lens member 8 and the QCL element 2, the incident surface 8a of the lens member 8 and the QCL element 2 (the end face 2b) can be more reliably separated from each other. As a result, it is possible to reduce the possibility that the incident surface 8a and the end face 2b come into contact with each other at the time of manufacturing (for example, at the time of an operation of disposing the lens member 8 with respect to the QCL element 2, or the like).

(Positional Relationship between QCL Element, First Lens Member, and Second Lens Member)

As illustrated in FIG. 3, a distance d1 (first distance) in the X-axis direction between the incident surface (that is, the second surface 6b of the first portion 601) of the lens member 6 (the first lens member) on which the light L1 emitted from the end face 2a of the QCL element 2 is incident and the end face 2a is shorter than a distance d2 (second distance) in the X-axis direction between the incident surface 8a of the lens member 8 (the second lens member) on which the light L3 emitted from the end face 2b of the QCL element 2 is incident and the end face 2b. That is, in the laser module 1, the working distance (the distance d1) of the lens member 6 (specifically, the first portion 601 functioning as a collimator lens) is shorter than the working distance (the distance d2) of the lens member 8. In the present embodiment, as an example, the distance d1 is 0.3 mm, and the distance d2 is 1 mm.

(Positional Relationship between QCL Element, First Lens Member, and Diffraction Grating Portion)

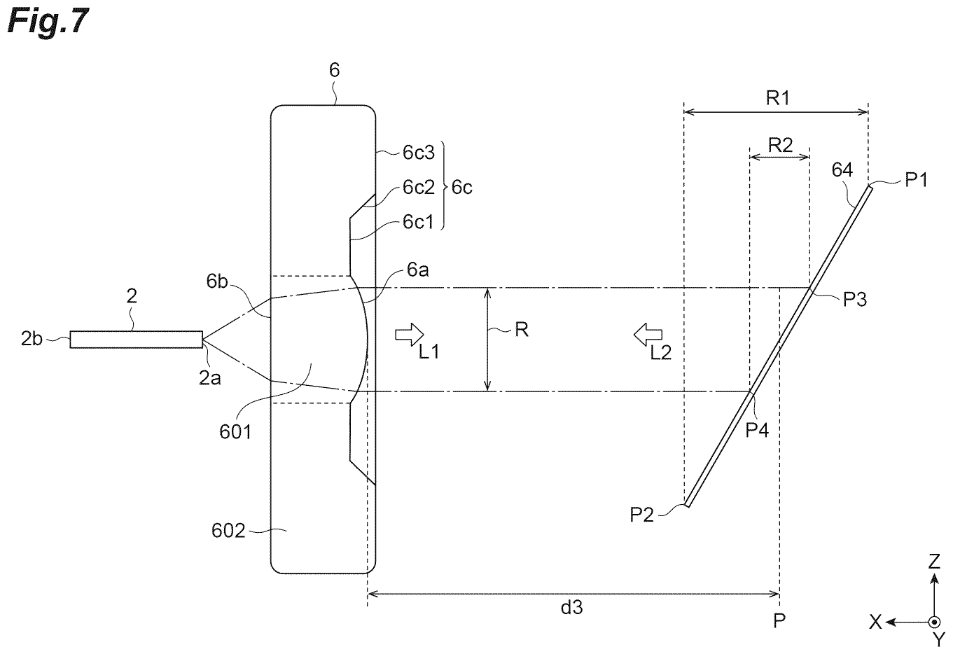

An example of the positional relationship between the QCL element 2, the lens member 6 (the first lens member), and the diffraction grating portion 64 will be described with reference to FIG. 7. As illustrated in FIG. 7, the light L1 emitted from the end face 2a of the QCL element 2 is incident on the second surface 6b of the first portion 601 of the lens member 6. At this time, since the light L1 is refracted at the second surface 6b, the parallelism of the traveling direction of the light L1 incident on the second surface 6b with respect to the X-axis direction is higher than the parallelism of the traveling direction of the light L1 before being incident on the second surface 6b with respect to the X-axis direction. The light L1 that has passed through the inside of the first portion 601 is emitted from the first surface 6a of the first portion 601 toward the diffraction grating portion 64. At this time, since the light L1 is refracted at the first surface 6a, the parallelism of the traveling direction of the light L1 emitted from the first surface 6a with respect to the X-axis direction is higher than the parallelism of the traveling direction of the light L1 before being emitted from the first surface 6a with respect to the X-axis direction. In this manner, the light L1 is collimated by being refracted at each of the second surface 6b and the first surface 6a of the first portion 601. Note that, in the present embodiment, collimation of the light L1 by the first portion 601 only needs to bring the light L1 passing through the first portion 601 and traveling toward the diffraction grating portion 64 closer to the parallel light than the light L1 before passing through the first portion 601, and the traveling direction of the light L1 collimated by the first portion 601 may be slightly shifted in a convergence direction or a diffusion direction than the ideal parallel light.

As described above, when viewed from the Y-axis direction, the diffraction grating portion 64 is inclined with respect to the Z-axis direction. A position P of the beam waist of the light L1 collimated by the first portion 601 is located between a position P1 (first position) of the upper end (one end) of the diffraction grating portion 64 in the Z-axis direction and a position P2 (second position) of the lower end (the other end) of the diffraction grating portion 64 in the Z-axis direction in the X-axis direction. That is, when viewed from the Y-axis direction, the position P of the beam waist of the light L1 is included in a region R1 between the position P1 and the position P2 in the X-axis direction. As described above, in the laser module 1, the relative positional relationship between the first portion 601 and the diffraction grating portion 64 is adjusted in such a manner that the position P of the beam waist of the light L1 is included in the range in which the diffraction grating portion 64 is present in the X-axis direction (that is, the region R1 between the position P1 and the position P2). As a result, the light L1 in a state of relatively high parallelism can be incident on the diffraction grating portion 64. As a result, the diffraction efficiency of the light L1 in the diffraction grating portion 64 is improved, and the amount of the light L2 appropriately returning to the QCL element 2 is increased. As described above, according to the laser module 1, it is possible to improve the output of the laser module. Note that it is only required that the position P of the beam waist of the light L1 described above is configured to be included in the region R1 (that is, the widest region of the region R1 that changes depending on the swing of the movable portion 63) between the position P1 and the position P2 when the diffraction grating portion 64 lies flattest (that is, when the inclination (the angle θ₁) of the diffraction grating portion 64 with respect to the Z-axis direction is maximum) in the range in which the movable portion 63 can swing. However, from the viewpoint of suitably exerting the effect of increasing the amount of the light L2 described above for each wavelength included in a wavelength sweep width, the position P of the beam waist of the light L1 is preferably configured to be included in the region R1 between the position P1 and the position P2 in any state in the range in which the movable portion 63 can swing. That is, it is preferable that the position P of the beam waist of the light L1 is included in the narrowest region of the region R1 that changes depending on the swing of the movable portion 63 (that is, the region R1 when the inclination (the angle θ₁) of the diffraction grating portion 64 with respect to the Z-axis direction is minimized).

In the present embodiment, the diffraction grating portion 64 is disposed in such a manner that the entire beam width region R of the light L1 is incident on the diffraction grating portion 64. Here, “beam width region R of the light L1” is a region (a so-called 1/e² width) between two points where the intensity of the light L1 is 1/e² of the peak intensity in the Z-axis direction. According to the above configuration, since the loss of the light L1 incident on the diffraction grating portion 64 can be effectively reduced, the amount of the light L2 can be further increased, and the output of the laser module 1 can be further improved accordingly.

Furthermore, the position P of the beam waist of the light L1 is located, in the X-axis direction, between a position P3 (third position) of the upper end (one end) in the Z-axis direction of the beam width region R of the light L1 incident on the diffraction grating portion 64 and a position P4 (fourth position) of the lower end (the other end) in the Z-axis direction of the beam width region R of the light L1 incident on the diffraction grating portion 64. That is, when viewed from the Y-axis direction, the position P of the beam waist of the light L1 is included in a region R2 between the position P3 and the position P4 in the X-axis direction. Here, as illustrated in FIG. 7, in a case where the entire beam width region R of the light L1 is incident on a region excluding both side edge portions in the direction D1 (see FIG. 4) of the diffraction grating portion 64, the position P3 is located on the left side (the side of the lens member 6) of the position P1. In addition, the position P4 is located on the right side (the side away from the lens member 6) of the position P2. That is, the region R2 is included in the region R1 and is narrower than the region R1. According to the above configuration, the light L1 can be incident on the diffraction grating portion 64 at a position closer to the beam waist (the position P). That is, the light L1 in a state of higher parallelism can be incident on the diffraction grating portion 64. As a result, the output of the laser module 1 can be more effectively improved. In addition, in the present embodiment, the first portion 601 (the lens member 6) is disposed so as to satisfy the requirement that the entire beam width region R of the light L1 falls within the first surface 6a when the light L1 passes through the first surface 6a facing the diffraction grating portion 64. According to the above configuration, the light L1 emitted from the end face 2a of the QCL element 2 can be efficiently guided to the diffraction grating portion 64 via the first portion 601. That is, it is possible to suppress the generation of light out of the first portion 601 of the light L1 (light that is not collimated and is not incident on the diffraction grating portion 64) and to reduce the loss of the light L1. As a result, the output of the laser module 1 can be more effectively improved. In the present embodiment, as an example, the stacked structure of the QCL element 2 is optimized in terms of a wavelength, a gain bandwidth, output, and the like, and in the optimized stacked structure, the radiation angle (the 1/e² width) in the vertical direction (the Z-axis direction) of the light L1 emitted from the end face 2a of the QCL element 2 is 104 degrees, and the radiation angle (the 1/e² width) in the horizontal direction (the Y-axis direction) of the light L1 is 70 degrees. In addition, as described above, the distance d1 (the working distance) between the second surface 6b of the first portion 601 and the end face 2a of the QCL element 2 is set to 0.30 mm, the diameter of the first portion 601 is set to 1.4 mm, and the thickness of the first portion 601 (the length in the X-axis direction from the central portion of the first surface 6a to the second surface 6b) is set to 1.1 mm. In the present embodiment, the structure that satisfies the above requirements is implemented by setting each parameter in this way.

In the present embodiment, the distance between the beam waist of the light L1 and the lens member 6, that is, the distance d3 between the central portion of the first surface 6a and the position P of the beam waist in the X-axis direction is 2 mm to 3 mm (2.5 mm as an example in the present embodiment). According to the above configuration, in a case where the QCL element 2, the lens portion (the first portion 601), and the diffraction grating portion 64 are housed in the same housing (the package 3) and packaged, the positional relationship between the lens member 6 and the diffraction grating portion 64 is adjusted so as to satisfy the condition described above (that is, the condition that the position P is included in the region R1 or R2), so that the package 3 can be appropriately downsized (that is, the laser module 1 can be appropriately downsized), and the effect described above can be obtained (that is, the output of the laser module 1 is improved by causing the light L1 with high parallelism to be incident on the diffraction grating portion 64).

To supplement the above, in the configuration of the conventional laser module, the same lens member as the lens member 8 is sometimes disposed between the QCL element 2 and the diffraction grating portion 64. Here, in the lens member 8 on the emission side for passing the emitted light (the laser light L) from the laser module 1, the beam waist position is set to a relatively far position in such a manner that the emitted light (the laser light L) is parallel light outside the package 3. Therefore, in the conventional configuration in which such a lens member similar to the lens member 8 is disposed between the QCL element 2 and the diffraction grating portion 64, the beam waist position of the light L1 passing through the lens member is located at a position farther from the diffraction grating portion 64 (a position opposite to the side of the diffraction grating portion 64 on which the QCL element 2 is disposed). Therefore, the light L1 incident on the diffraction grating portion 64 has relatively low parallelism. In addition, the plurality of grating grooves 64a included in the diffraction grating portion 64 are designed on the assumption that light incident on the diffraction grating portion 64 is parallel light. For this reason, if the light L1 with low parallelism is incident on the diffraction grating portion 64, there may be a problem that the amount of the appropriately returned light L2 is reduced or the wavelength sweep width is reduced due to a deviation from the design value. In contrast, according to the laser module 1 described above, since the position P of the beam waist is adjusted to match the position of the diffraction grating portion 64 using the microlens (the first portion 601), the light L1 with high parallelism can be incident on the diffraction grating portion 64. As a result, the problem described above can be solved. That is, as compared with the conventional configuration, the amount of the light L2 can be increased, the output of the laser module 1 (the output of the laser light L) can be improved, and the wavelength sweep width can be increased. Note that, if the beam waist position of the lens member 8 is present in the package 3, the beam (the laser light L) spreads at a position where the measurement target is irradiated with the laser light L emitted from the laser module 1 (outside the package 3), so that it is difficult to use the laser module 1 for spectroscopic measurement. For this reason, in the laser module 1, a microlens such as the lens member 6 is not used as the lens member 8.

In the laser module 1 described above, the optical member (in the present embodiment, the lens member 6) disposed between the QCL element 2 and the diffraction grating portion 64 includes the first portion 601 constituting the collimator lens that collimates the light L1, and the second portion 602 that is connected to the outer edge portion of the first portion 601 and does not constitute the collimator lens. In other words, the lens member 6 includes the first portion 601 (that is, a portion functioning as a lens that suppresses the beam spread of the light L1 from the QCL element 2 toward the diffraction grating portion 64) having the first surface 6a formed in a curved surface shape convex toward the diffraction grating portion 64, and the second portion 602 connected to the outer edge portion of the first portion 601. According to the above configuration, the lens with a smaller lens diameter than that of a conventional lens (in the present embodiment, a microlens with a diameter of 1.4 mm) can be easily implemented by the first portion 601. Here, the diffraction grating portion 64 is preferably disposed at a position as close as possible to the beam waist position of the lens. That is, the diffraction grating portion 64 is preferably irradiated with a beam close to parallel light. Therefore, by forming the lens (the first portion 601) with a lens diameter smaller than that of a conventional lens as described above, the beam waist position can be brought close to the lens, and the diffraction grating portion 64 can be disposed close to the lens member 6. As a result, the laser module 1 can be downsized (can be made compact). In addition, in the second portion 602, the lens member 6 can be supported (held) without hindering the lens function of the first portion 601. This makes it possible to achieve both downsizing of the first portion 601 functioning as a collimator lens and ease of supporting the lens member 6. As described above, according to the laser module 1, it is possible to facilitate the support of the lens (that is, the first portion 601 included in the lens member 6) disposed between the QCL element 2 and the diffraction grating portion 64 while improving the output of the laser module 1. In addition, by configuring the lens member 6 to have the first portion 601 and the second portion 602, handling of the lens member 6 when the lens member 6 is attached to the lens holder 7 becomes easy. For example, in a case where a portion having a lens function is held, it is necessary to carefully hold the portion from the viewpoint of suppressing scratches, damage, and the like of the lens. On the other hand, by providing the second portion 602 not having the lens function in the lens member 6, the second portion 602 can be held to hold the lens member 6.

The laser module 1 includes the package 3 that houses the QCL element 2, the diffraction grating portion 64, and the lens member 6 and in which the optical path between the diffraction grating portion 64 and the incident surface 8a of the lens member 8 is disposed. In addition, as illustrated in FIG. 3, the distance d1 in the X-axis direction between the incident surface (the second surface 6b of the first portion 601) of the lens member 6 on which the light L1 is incident and the end face 2a of the QCL element 2 is shorter than the distance d2 in the X-axis direction between the incident surface 8a of the lens member 8 on which the light L3 is incident and the end face 2b of the QCL element 2. By reducing the distance d1, the length of the laser module 1 (the package 3) in the X-axis direction can be reduced, and the beam diameter of the light L1 traveling toward the diffraction grating portion 64 via the lens member 6 can be reduced, so that the diffraction grating portion 64 can be downsized. Therefore, by reducing the distance d1, the laser module 1 can be more effectively downsized than by reducing the distance d2. That is, reducing the distance d1 contributes to downsizing of the laser module 1 as compared with reducing the distance d2 by the same distance. On the other hand, the length of the laser module 1 in the X-axis direction can be reduced by reducing the distance d2 similarly to the distance d1. However, in a case where both the distances d1 and d2 are similarly reduced, at the time of manufacturing the laser module 1 (for example, at the time of positioning the lens member 6 and the lens member 8 with respect to the QCL element 2, or the like), the end face 2a or the end face 2b of the QCL element 2 comes into contact with the lens member 6 or the lens member 8, and there is an increased risk that the end faces 2a and 2b, which play an important role in laser oscillation of the QCL element 2, are damaged. In contrast, according to the laser module 1, by preferentially reducing the distance d1 (that is, by making the distance d1 shorter than the distance d2), the advantage that the laser module 1 can be effectively downsized is obtained as described above, and at the same time, by making the distance d2 longer than the distance d1, the spatial margin between the end face 2b of the QCL element 2 and the lens member 8 is ensured, and the risk of damage to the QCL element 2 at the time of manufacturing, which has been described above, can be reduced. That is, it is possible to suitably downsize the laser module 1 while suppressing a decrease in the yield of the laser module 1.

The distance d1 is ½ or less of the distance d2. In the present embodiment, the distance d1 is 0.3 mm, and the distance d2 is 1 mm. According to the above configuration, the effect described above can be more reliably obtained. That is, it is possible to more effectively achieve both suppression of yield reduction and downsizing of the laser module 1.

The second surface 6b and the fourth surface 6d of the lens member 6 are not supported by the lens holder 7. That is, the lens holder 7 is not disposed between the lens member 6 and the end face 2a of the QCL element 2. As a result, the distance d1 (the distance between the second surface 6b and the end face 2a) can be further reduced. More specifically, in a case where a part of the lens holder 7 is disposed between the lens member 6 and the QCL element 2, there may be a restriction that the distance d1 cannot be reduced by a certain amount or more due to the interference of the part, but such a restriction can be eliminated by not disposing the lens holder 7 between the lens member 6 and the QCL element 2 as described above.

The lens member 6 is inserted into the large-diameter hole 7b of the lens holder 7, and at least a part (in the present embodiment, a part of the outer flat surface 6c3) of the lens member 6 facing the diffraction grating portion 64 is supported in surface contact with the counterbore surface 7c. According to the above configuration, the lens holder 7 having the small-diameter hole 7a, the large-diameter hole 7b, and the counterbore surface 7c is used to support the lens member 6 in surface contact with the counterbore surface 7c, so that it is possible to stably support the lens member 6 while implementing the configuration in which the lens holder 7 is not disposed between the lens member 6 and the end face 2a of the QCL element 2 as described above. As a result, the reliability of the laser module 1 can be enhanced, and the yield can be improved.

The second portion 602 is directly supported by the lens holder 7, and the first portion 601 is not directly supported by the lens holder 7. As described above, by reducing the distance d1, the first portion 601 constituting the collimator lens in the lens member 6 can be reduced in size, and the second portion 602 not constituting the collimator lens can be provided at the outer edge portion thereof. Therefore, by directly supporting only the second portion 602 that does not have a lens function by the lens holder 7, it is possible to prevent the first portion 601 having the lens function from coming into contact with the lens holder 7 and being damaged. As a result, the reliability of the laser module 1 can be enhanced, and the yield can be improved. In addition, since the lens holder 7 does not come into contact with the first portion 601, a part of the light L1 passing through the first portion 601 can be prevented from being blocked by the lens holder 7.

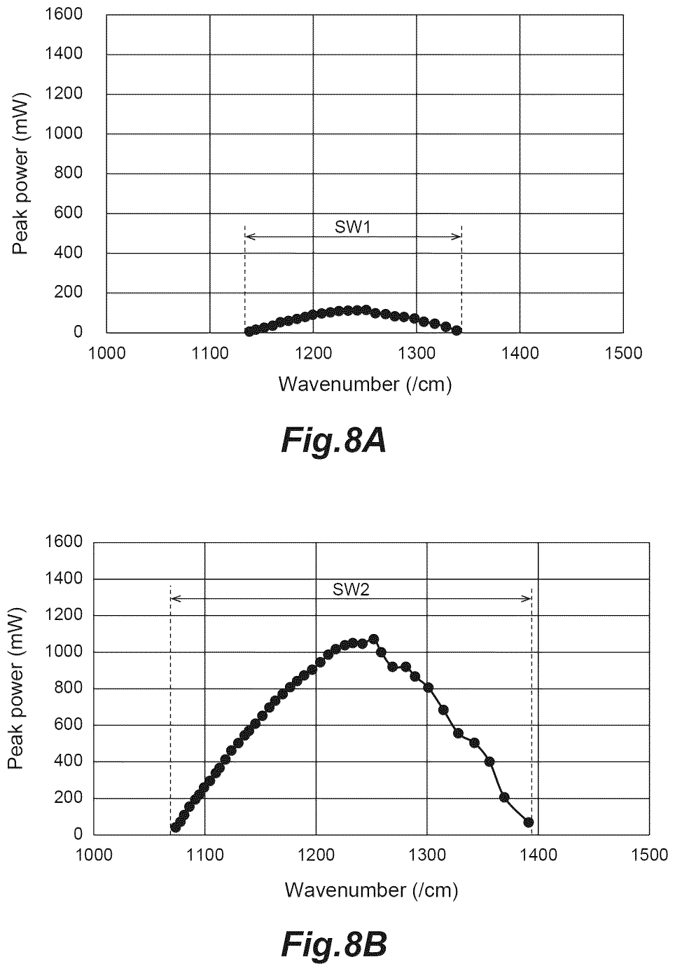

FIG. 8A illustrates measurement results of a wavelength (a horizontal axis) and output (a vertical axis) of a conventional configuration, that is, a configuration (a comparative example) using a lens member formed of a material (ZnSe) similar to that of the lens member 8 and having a diameter (5 mm) similar to that of the lens member 8, as the lens member 6. FIG. 8B illustrates measurement results of the wavelength (the horizontal axis) and the output (the vertical axis) of an example (that is, the configuration of the laser module 1 described above). As illustrated in FIGS. 8A and 8B, according to the example (the laser module 1), it has been confirmed that the output of the output light (the laser light L) of the laser module can be improved from conventional output of about 200 mW to output of about 1000 mW, as compared with the comparative example. In addition, it has also been confirmed that, for the wavelength sweep width of the movable diffraction grating 51, a wavelength sweep width SW2 of the example is increased to about 1.5 times (about 300 cm⁻¹) a wavelength sweep width SW1 (about 200 cm⁻¹) of the conventional configuration (the comparative example). It is considered that such an effect of improving the output and increasing the wavelength sweep width is exerted by the following action. That is, the diffraction grating portion 64 is designed on the premise that parallel light is emitted. In other words, the diffraction grating portion 64 is configured to have the highest diffraction efficiency when irradiated with the parallel light. In addition, the higher the diffraction efficiency, the larger the light output fed back from the diffraction grating portion 64 to the QCL element 2. In addition, such large light output fed back to the QCL element 2 means that the performance of the resonator configured by the QCL element 2 and the diffraction grating portion 64 is high (that is, the oscillation threshold of the resonator is low) and laser oscillation is likely to occur. In a case where the oscillation threshold is low, laser oscillation can be obtained even in a wavelength region with a low gain (a tail of gain) away from the gain peak. As a result, the wavelength sweep width is widened. In the example (the laser module 1), since the diffraction grating portion 64 is configured to be irradiated with the light L1 close to the parallel light, it is considered that the action described above occurs, and as a result, the effect of improving the output and increasing the wavelength sweep width is suitably exhibited.

### Modifications

The present disclosure is not limited to the above embodiment. The material and shape of each configuration are not limited to the material and shape described above, and various materials and shapes can be employed. In addition, some configurations included in the laser module 1 according to the above embodiment may be omitted or changed as appropriate. For example, in the above embodiment, some characteristic configurations included in the laser module 1 and some effects exhibited by each configuration have been described, but the laser module according to the present disclosure does not necessarily need to be configured to exhibit all the effects described in the above embodiment, and may be configured to exhibit only some of the effects described in the above embodiment. In the latter case, the laser module is only required to have a configuration essential for exerting at least the partial effect, and a configuration that is not essential for exerting the partial effect may be omitted or changed as appropriate. Note that, in a case where one effect is focused on, the configuration essential for exerting the one effect should be reasonably grasped based on the technical common sense and the description of the present specification on the basis of those skilled in the art. Hereinafter, some specific modifications of the laser module according to the present disclosure will be illustrated.

The second portion 602 may be formed of a member different from the first portion 601. For example, the second portion 602 may be formed of a metal member that surrounds the side surface of the first portion 601 and supports the first portion 601. According to the above modification, it is not assumed that the light L1 and L2 passes as illustrated in FIG. 7 (that is, it is not necessary to function as a lens), and the second portion 602 that does not require optical design is formed of a member (for example, a metal or the like that is easily fixed to the lens holder 7) different from the first portion 601, so that the degree of freedom in designing the lens member 6 can be increased and the reliability of the laser module can be improved. In addition, since the mechanical strength of the bonding portion between the second portion 602 and the lens holder 7 can be ensured, it is possible to suppress chipping and damage of the bonding portion when the second portion 602 is bonded to the lens holder 7.

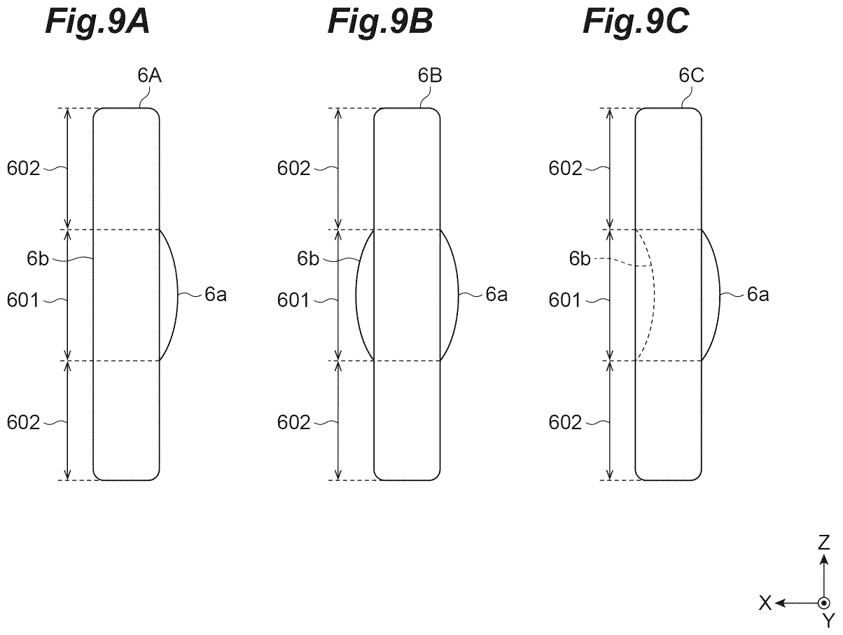

In addition, the configuration such as the shape of the first portion 601 and the second portion 602 of the lens member 6 is not limited to the configuration exemplified in the above embodiment (see FIG. 6). FIGS. 9A to 9C illustrate three modifications of a lens member disposed between the QCL element 2 and the diffraction grating portion 64.

In a lens member 6A according to a first modification illustrated in FIG. 9A, the thickness of a portion of the first portion 601 except for the convex portion including the first surface 6a is the same as the thickness of the second portion 602. That is, the second portion 602 of the lens member 6A does not have the inner flat surface 6cl, the inclined surface 6c2, and the outer flat surface 6c3. In this example, the diameter of the entire lens member 6A (a portion combining the first portion 601 and the second portion 602) is 5 mm, and the diameter of the first portion 601 functioning as a collimator lens is 2.0 mm. In addition, the thickness of the second portion 602 in the X-axis direction is 1.085 mm, and the length from the apex (the center) of the first surface 6a to the second surface 6b in the X-axis direction is 1.3 mm. Furthermore, the working distance (the distance d1) of the lens member 6A is 0.40 mm.

A lens member 6B according to a second modification illustrated in FIG. 9B is different from the lens member 6A in that the second surface 6b of the first portion 601 is formed in a curved surface shape convex outward (to the side of the QCL element 2). Other configurations of the lens member 6B are similar to those of the lens member 6A. A lens member 6C according to a third modification illustrated in FIG. 9C is different from the lens member 6A in that the second surface 6b of the first portion 601 is formed in a curved surface shape convex inward (to the side of the diffraction grating portion 64) (that is, the second surface 6b is recessed inward). Other configurations of the lens member 6C are similar to those of the lens member 6A. Like the lens members 6B and 6C, the second surface 6b of the first portion 601 may be formed in a curved surface shape. According to the lens members 6B and 6C, the degree of freedom in lens design is improved, and it is easy to manufacture a lens with small various aberrations. In addition, according to the lens member 6B, it is also possible to obtain an effect of reducing return light (light reflected by the second surface 6b and directed toward the end face 2a of the QCL element 2) that adversely affects laser oscillation.

The lens member 8 disposed to face the end face 2b of the QCL element 2 may be provided outside the package 3. That is, the package 3 is only required to house the QCL element 2, the diffraction grating portion 64 (the diffraction grating unit 5), and the lens member 6, and the optical path between the diffraction grating portion 64 and the incident surface 8a of the lens member 8 is only required to be disposed therein, and the lens member 8 itself may be disposed outside the package 3. For example, the lens member 8 may be provided in the opening of the second side wall 322, instead of the light exit window 12. In this case, the light exit window 12, the lens holder 9, and the first mounting portion 41 of the mount member 4 can be omitted. In addition, the length of the package 3 in the X-axis direction can be reduced by omitting the lens holder 9 and the first mounting portion 41.

Furthermore, the laser module does not need to include the lens holder 7. For example, the lower portion of the second portion 602 of the lens member 6 may be directly fixed to the upper surface 43a of the third mounting portion 43 by an adhesive (for example, a photocurable resin or the like). In this case, the adhesive (the adhesive in a cured state) functions as a support member that supports the lens member 6. The lens holder 9 may also be omitted similarly to the lens holder 7.

In addition, it is not essential to provide the second portion 602 in order to implement the structure satisfying the requirements (that is, the requirements that the position P of the beam waist of the light L1 is included in the region R1 or R2) illustrated in FIG. 7. For example, a lens member (a lens portion) including only the first portion 601 may be directly supported by a lens holder or the like prepared based on the size of the lens portion. However, as described in the above embodiment, since it is difficult to directly and stably hold the lens (the microlens) including only the first portion 601, it is preferable to provide the second portion 602 as in the above embodiment from the viewpoint of facilitating the support structure.

In the above embodiment, the second portion 602 is formed in an annular shape surrounding the entire circumference of the first portion 601 when viewed from the X-axis direction, but the second portion may be connected to only a part of the outer edge portion of the first portion when viewed from the X-axis direction. For example, the second portion may be configured as a rod-shaped member that is connected to the outer edge portion of the lower half of the first portion and extends downward when viewed from the X-axis direction.

What is claimed is:

1. A laser module comprising:
a quantum cascade laser element having a stacked structure including an active layer and paired cladding layers arranged on both sides of the active layer, and a first end face and a second end face facing each other in a second direction orthogonal to a first direction as a stacking direction of the stacked structure, the quantum cascade laser element being configured to emit light from each of the first end face and the second end face;
a diffraction grating portion configured to diffract and reflect first light emitted from the first end face and return second light as a part of the first light to the first end face;
an optical member configured to be disposed between the first end face and the diffraction grating portion and allow the first light and the second light to pass therethrough; and
a support member configured to support the optical member, wherein
the optical member includes
a first portion configured to constitute a collimator lens collimating the first light, and
a second portion configured to be connected to an outer edge portion of the first portion when viewed from the second direction and not to constitute the collimator lens.

2. A laser module comprising:
a quantum cascade laser element having a stacked structure including an active layer and paired cladding layers arranged on both sides of the active layer, and a first end face and a second end face facing each other in a second direction orthogonal to a first direction as a stacking direction of the stacked structure, the quantum cascade laser element being configured to emit light from each of the first end face and the second end face;
a diffraction grating portion configured to diffract and reflect first light emitted from the first end face and return second light as a part of the first light to the first end face;
an optical member configured to be disposed between the first end face and the diffraction grating portion and allow the first light and the second light to pass therethrough; and
a support member configured to support the optical member, wherein
the optical member includes
a first portion configured to include a first surface facing the diffraction grating portion and a second surface facing the quantum cascade laser element, and to cause at least the first surface to be formed in a curved surface shape convex toward the diffraction grating portion, and
a second portion configured to include a third surface connected to an outer edge portion of the first portion and having a planar portion when viewed from the second direction, and a fourth surface connected to an outer edge portion of the second surface and having a planar portion when viewed from the second direction.

3. The laser module according to claim 1, wherein at a boundary portion between the first portion and the second portion on a side of the optical member on which the diffraction grating portion is located, a curved surface portion included in the first portion and a planar portion included in the second portion are connected to each other.

4. The laser module according to claim 1, wherein the second portion surrounds the first portion when viewed from the second direction.

5. The laser module according to claim 1, wherein
the second portion is directly supported by the support member, and
the first portion is not directly supported by the support member.

6. The laser module according to claim 1, wherein the optical member is formed of chalcogenide.

7. The laser module according to claim 1, wherein a surface of the optical member facing the quantum cascade laser element is not supported by the support member.

8. The laser module according to claim 7, wherein
the support member includes
a first hole configured to be open to a side of the diffraction grating portion,
a second hole configured to include the first hole, be larger than the first hole, and be open to a side of the quantum cascade laser element when viewed from the second direction, and
a counterbore surface configured to connect the first hole and the second hole and extend along a plane intersecting the second direction,
the optical member is inserted into the second hole, and
at least a part of the second portion facing the diffraction grating portion is supported in surface contact with the counterbore surface.

9. The laser module according to claim 1, wherein the second portion is formed of a member different from the first portion.

10. The laser module according to claim 1, wherein an area of the second portion is larger than an area of the first portion when viewed from the second direction.

11. The laser module according to claim 1, wherein
the optical member is disposed so as to cause, when the first light passes through a first surface of the first portion facing the diffraction grating portion, all of a beam width region of the first light to fall within the first surface, and
the beam width region of the first light is a region between two points at which intensity of the first light is 1/e² of peak intensity in the first direction.

12. The laser module according to claim 1, wherein
an antireflection film is formed on at least one of a surface facing the quantum cascade laser element or a surface facing the diffraction grating portion in the first portion and the second portion, and
when viewed from the second direction, an outer edge portion of the antireflection film is located inside an outer edge portion of the second portion.
